(19) United States
(12) Patent Application Publication
(10) Pub. No.: US 2007/0164797 A1
(43) Pub. Date: Jul. 19, 2007

(54) Method and apparatus to eliminate clock phase error in a multi-phase clock circuit

(76) Inventors: Hon-Mo Raymond Law, Beaverton, OR (US); Ying L. Zhou, Portland, OR (US)

Correspondence Address: MARGER JOHNSON & MCCOLLOM, P.C., 210 SW MORRISON STREET, SUITE 400, PORTLAND, OR, 97204, US

(21) Appl. No.: 11/314,038

(22) Filed: Dec. 20, 2005

(51) Int. Cl. H03L 7/06

(52) U.S. Cl. 327/149

(57) ABSTRACT

A multi-phase clock circuit may include a delay line with an input terminal for receiving a periodic signal, a phase detector for detecting a phase difference between the periodic signal and a delay-line output signal generated in response to the periodic signal, and a bias control circuit for adjusting at least one bias voltage applied to the delay line in response to a signal related to the detected phase difference. A method for generating a multi-phase clock is also provided. This method includes applying a reference clock signal to a delay line, comparing the phase of a delay line output signal generated in response to the reference clock with the reference clock, and adjusting at least one bias voltage of the delay line in response to the phase comparison of the two signals.

### FIELD OF THE INVENTION

The present invention relates generally to multi-phase clock circuits and more particularly to such circuits that are implemented with a master phase or delay locked loop circuit and a plurality of slave delay lines.

### BACKGROUND

FIG. 1 illustrates a prior art multi-phase clock circuit. The prior art clock circuit 10, indicated generally at 10, includes a master locked-loop signal generator 12, a plurality of slave delay lines 14, and a plurality of bias control circuits 16. The master locked-loop signal generator, which may include a phase locked-loop (PLL) or delay locked-loop (DLL) circuit, generates a control signal on line 18 and a reference clock signal on line 20. The reference clock signal on line 20, or other periodic reference signals with the same frequency as the generated clock signal on line 20, such as Rx Clock on line 19, is applied to each of the plurality of slave delay lines 14. The generated control signal on line 18 is also applied to each of the slave delay lines 14 and to the bias control circuits 16. The bias control circuits 16 generate an output signal including bias control voltages on line 17. These output signals on line 17 are applied to each of the slave delay lines 14, respectively. The slave delay lines may include a plurality of buffer or inverter stages (such as third stage 22 and fifth stage 24) that may be used to generate a multi-phase clock. The delay-per-stage of each slave delay line 14 is determined from the output signal on line 17 and from the control signal on line 18 generated by the locked-loop signal generator 12.

This clock circuit is structured to provide consistent timing between slave delay lines. In particular, the master locked-loop signal generator 12 determines the reference clock signal on line 20 and the corresponding control signal on line 18, and the remote slave delay lines 14 generate multi-phased clocks based on these applied signals. This configuration thus allows different slave delay lines 14 to have the same delay-per-stage because they are all slave circuits controlled by the control signal generated from the master locked-loop generator. As such, the master locked-loop generator controls the phase shifts involved in generating the multi-phase clock.

However, due to on-die mismatches, such as process variations and/or local temperature or voltage differences, the delay-per-stage of respective delay lines 14 may differ from one another. This difference in delay-per-stage translates directly to clock phase error. Current devices attempt to overcome this clock phase error by over-designing the system. This over-design, however, must be added to the timing budget and becomes burdensome for high-speed input/output (I/O) systems.

### BRIEF DESCRIPTION OF THE DRAWINGS

FIG. 1 illustrates a prior art clock circuit.

FIG. 2 illustrates an embodiment of a clock circuit according to the inventive principles of this patent disclosure.

FIG. 3 illustrates an additional embodiment of a clock circuit according to the inventive principles of this patent disclosure.

FIG. 4 illustrates an example of a delay stage circuit used in the embodiments illustrated in FIGS. 2 and 3 of this patent disclosure.

FIG. 5 illustrates an example of a control signal distribution circuit used in the embodiments illustrated in FIGS. 2 and 3 of this patent disclosure.

FIG. 6 illustrates an embodiment of a phase detector circuit and digital control circuit according to the inventive principles of this patent disclosure.

FIG. 7 illustrates an embodiment of a local bias control circuit according to the inventive principles of this patent disclosure.

FIG. 8 illustrates an example of experimental tuning results according to the inventive principles of this patent disclosure.

FIG. 9 illustrates an embodiment of a method for implementing a clock circuit according to the inventive principles of this patent disclosure.

### DETAILED DESCRIPTION

The inventive principles may be realized in myriad embodiments. Although some specific details are shown for purposes of illustrating the inventive principles, numerous other arrangements may be devised in accordance with the inventive principles of this patent disclosure. Thus, the inventive principles are not limited to the specific details disclosed herein.

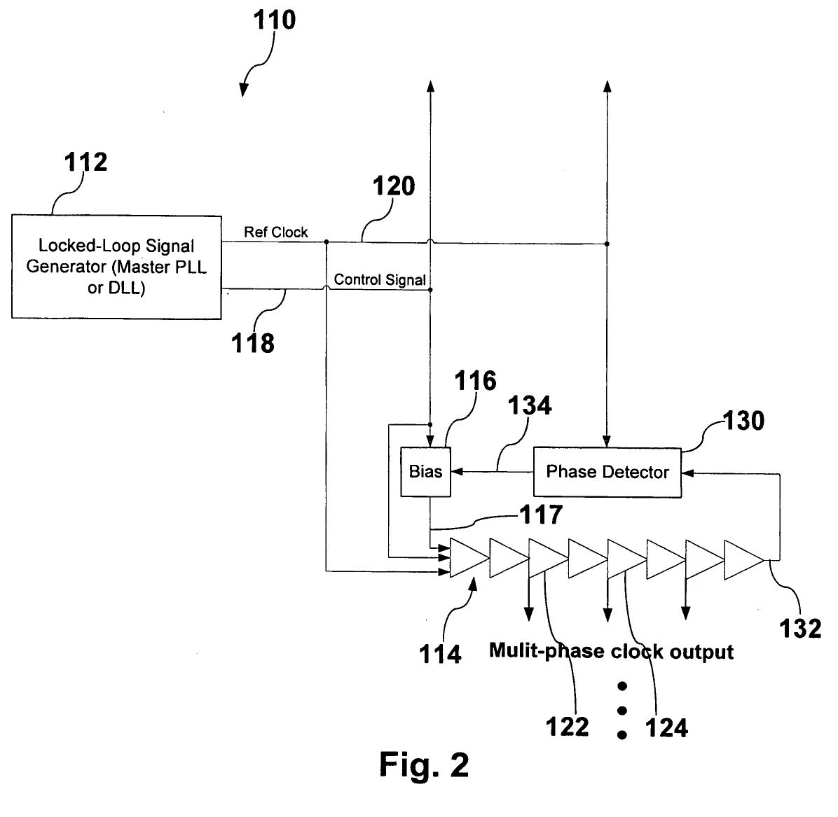

FIG. 2 illustrates an embodiment of a clock circuit according to the inventive principles of this patent disclosure. Referring to the embodiment illustrated in FIG. 2, a clock circuit 110 includes a locked-loop signal generator 112, a delay line 114, a bias control circuit 116, and a phase detector 130. As indicated in the drawing, circuit 110 may include multiple groups, each including a delay line, a bias control circuit, and a phase detector. However, only one such group is illustrated in FIG. 2. The clock circuit 10 generates a multi-phase clock by having the locked-loop signal generator 112 control the delay-per-stage of the delay line 114, thus controlling the phase shifts of the multi-phase clock outputs. The phase detector 130 and bias control circuit 116 are used to monitor clock phase error in the delay line 114 and provide fine tuning adjustments to the delay-per-stage and generated clock phases of the delay line 114 by adjusting one or more bias control voltages applied to the delay line.

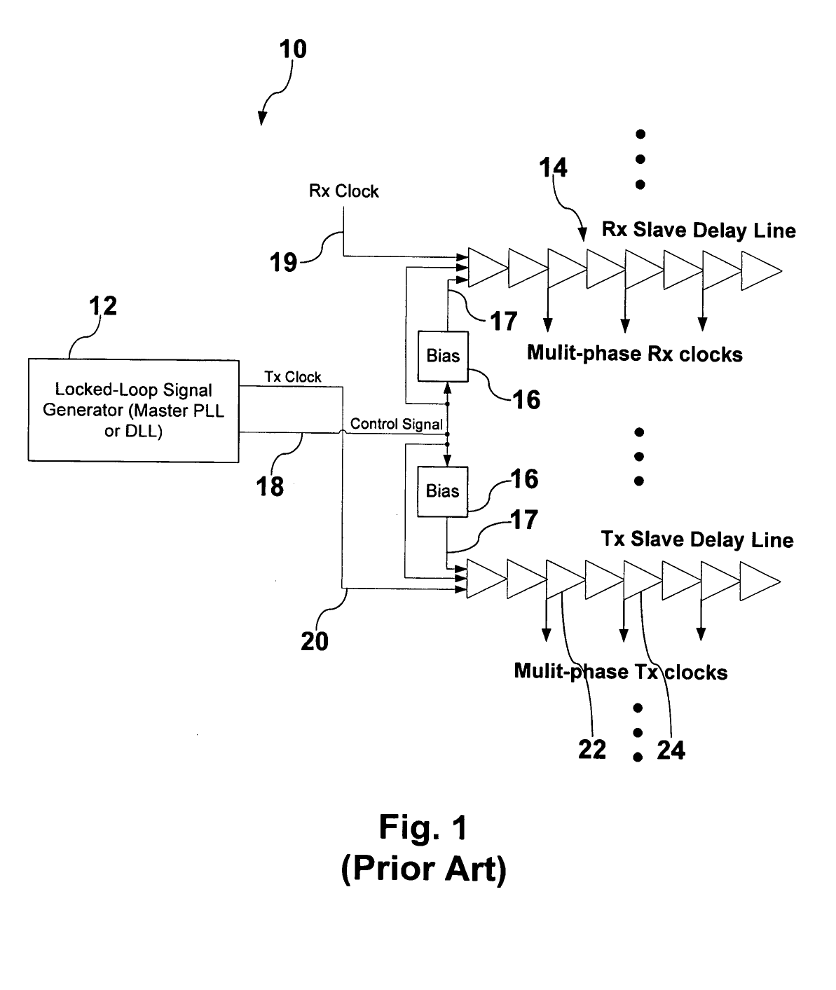

Referring again to FIG. 2, a periodic reference signal on line 120 is applied by the locked-loop signal generator 112 to the delay line 114 and to the phase detector 130. Although the embodiment of FIG. 2 illustrates the periodic reference signal on line 120 as being generated by the locked-loop signal generator 112, another periodic reference signal with the same frequency as the reference signal generated by the locked-loop signal generator 112, such as Rx Clock on line 19 in FIG. 1, may be applied to delay line 114. The delay line 114 generates an output signal on line 132 in response to the applied periodic reference signal on line 120. The delay line output signal on line 132 is fed back to the phase detector 130. The phase detector 130 detects a phase difference between the delay line output signal on line 132 and the periodic reference signal on line 120. As a result of this phase detection process, the phase detector 130 generates an output signal on line 134, which is applied to the bias control circuit 116. The bias control circuit may then adjust one or more bias control voltages applied to the delay line 114 from an output signal on line 117 in response to the phase detector output signal.

The locked-loop signal generator 112 may have a phase locked-loop (PLL) configuration, a delay locked-loop (DLL) configuration, or another type of configuration that allows it to generate the periodic reference signal on line 120 and the control signal on line 118. In the embodiment illustrated in FIG. 2, the locked-loop signal generator 112 may act as a master circuit and the delay line 114 may act as a slave circuit. In this master/slave configuration, the locked-loop signal generator 112 generates a control signal on line 118 that controls a delay-per-stage of the delay line 114. To insure that the delay line 114 has the proper delay-per-stage, the locked-loop signal generator 112 may also include delay stage logic identical to the delay stage logic used in each delay stage of the delay line 114. This master/slave delay control may be realized by providing one or more control voltages to the delay line 114 in the form of the control signal on line 118. The control signal on line 118 may also use a control current signal distribution scheme to route the control signal on line 118 from the locked-loop signal generator 112 to the delay line 114. Control current signal distribution provides better noise immunity when a control signal is routed across significant distances. Additionally, the periodic reference signal on line 120 may include a clock signal or other types of signals that have a periodic character.

The delay line 114 may include a plurality of inverters, such as 122, 124, in a series configuration. The delay in each inverter (delay-per-stage) may be controlled by locked-loop signal generator 112 through the applied control signal on line 118, and by the bias control circuit output signal on line 117. In this embodiment, the delay line 114 generates a multi-phase clock signal based on the periodic reference signal on line 120, the applied control signal on line 118 from the locked-loop signal generator 112, and from the bias control output signal on line 117. Each phase of the multi-phase clock has the same frequency, but lags previous phases by one or more phase intervals based on the delay-per-stage. As mentioned above, the delay line 114 also generates an output signal on line 132 in response to the applied signals. This output signal on line 132 is routed back to the phase detector 130 to provide feedback control.

As mentioned above, the phase detector 130 compares the delay line output signal on line 132 with the periodic reference signal on line 120 and detects a phase difference between the two signals. The phase detection process may be carried out in a variety of ways. In some embodiments, the phase detector 130 may include an exclusive OR gate and/or include a plurality of flip-flops (not shown) to output control signals based on the detected phase difference of the signals. In other embodiments, the phase detector 130 may include a linear multiplier (not shown) to generate a low-frequency signal whose amplitude is related to the phase difference. Once the phase detection process is complete, the phase detector 130 generates the output signal on line 134 that is applied to the bias control circuit 116.

The bias control circuit 116, as described above, adjusts at least one bias control voltage applied to the delay line 114 from the bias control circuit output signal on line 117 in response to the detected phase difference. In the embodiment illustrated in FIG. 2, the bias control circuit 116 receives the phase detector output signal on line 134 and the control signal on line 118 from the locked-loop signal generator 112. In response to these applied signals, the bias control circuit 116 of this embodiment adjusts at least one bias voltage 117 of the delay line 114.

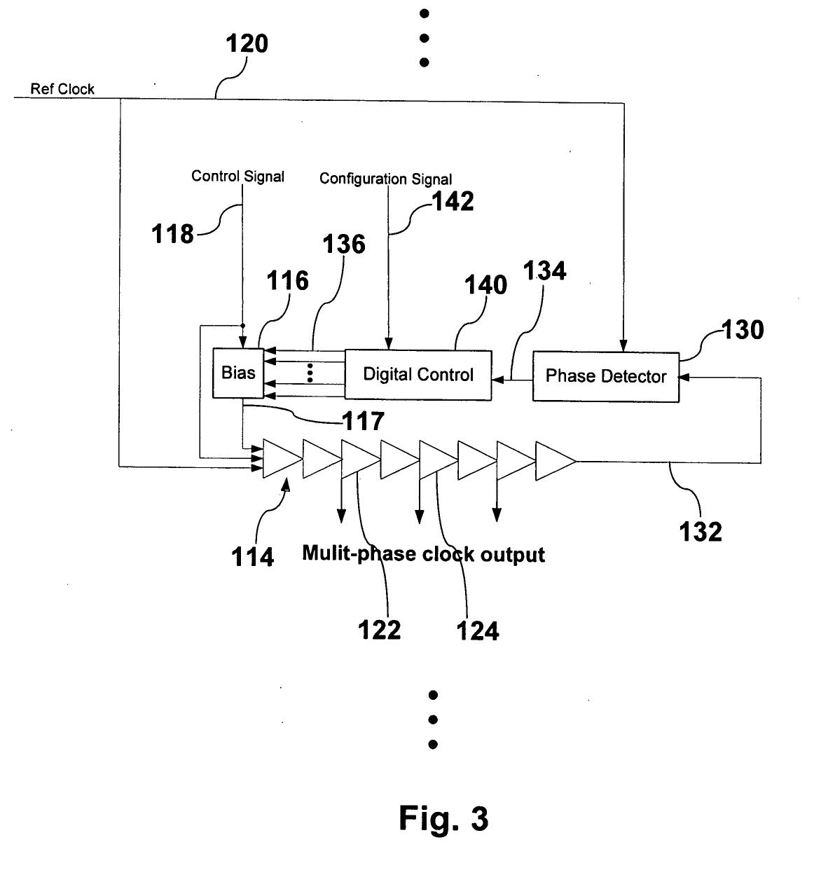

FIG. 3 illustrates an additional embodiment of a clock circuit according to the inventive principles of this patent disclosure. The embodiment illustrated in FIG. 3 is similar to the embodiment illustrated in FIG. 2 with the addition of a digital control unit 140 placed between the phase detector 130 and the bias control circuit 116. In the embodiment illustrated in FIG. 3, the phase detector output signal on line 134 is applied to the digital control unit, which in turn generates a plurality of digital control signals on lines 136 (also referred to herein as digital control codes) to tune the bias control circuit 116.

Additionally, a configuration signal on line 142 may be applied to the digital control unit 140 to determine an operation mode of the digital control unit. Various operating modes include “disable,” “lock once and freeze,” “periodic re-lock and freeze,” and “continuous running.” In the “disable” mode, the digital control unit 140 is disabled and the control signal on line 118 is used without any adjustment to determine the delay-per-stage of the delay line 114. In the “lock once and freeze” mode, the digital control unit 140 allows a single adjustment and then locks the resultant digital control codes for further cycles. This type of operational mode may be useful during a power-up operation when the digital control codes need only be set once to avoid clock phase error. In the “periodic re-lock and freeze” mode, the digital control unit 140 periodically allows new digital control codes on lines 136 to be locked and used for a particular amount of time. This type of operational mode may be useful if a periodic recheck of clock phase is desired without the overhead of a continuously running system. In the “continuous running” mode, the digital control unit 140 receives continuous feedback information about the clock phase and generates the appropriate digital control codes on lines 136 to tune the bias control circuit 116 as needed. While these operational modes may be factory set based on a product type, it is also possible to provide a user input mechanism to allow a desired operational mode to be selected.

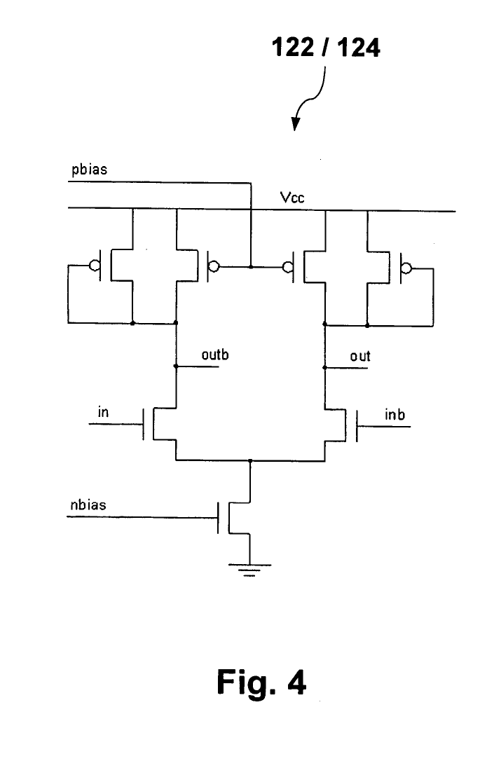

FIG. 4 illustrates an example of a delay stage circuit used in the embodiments illustrated in FIGS. 2 and 3 of this patent disclosure. Referring to FIG. 4, the circuit illustrated is included in one of the delay stages, such as delay stages 122, 124, of delay line 114. The output lines out and outb are respectively connected to input lines in and inb of a subsequently coupled delay stage. The control voltage lines pbias and nbias are used in determining the delay at the stage. In addition, the locked-loop signal generator 112 may include similar circuitry so that the master reference circuit and the slave delay line 114 have the same delay stage.

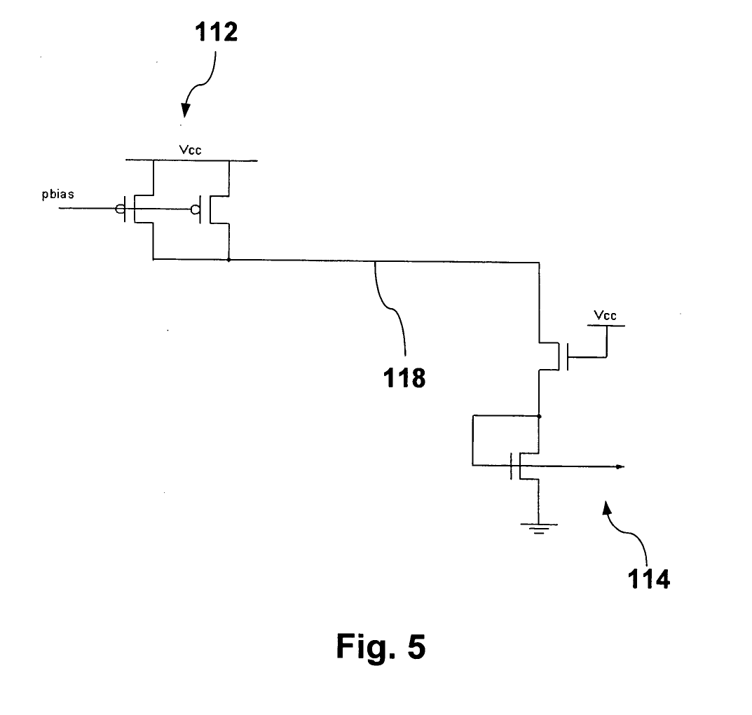

FIG. 5 illustrates an example of a control signal distribution circuit used in the embodiments illustrated in FIGS. 2 and 3 of this patent disclosure. Referring to FIG. 5, the control signal distribution circuit begins in the locked-loop signal generator 112, where control signals are structured into current controlled signals that are routed to the delay line 114, where the control voltages are replicated by the circuitry contained in the delay line 114. As mentioned above, current controlled signal distribution provides better noise immunity when a signal line covers a significant distance.

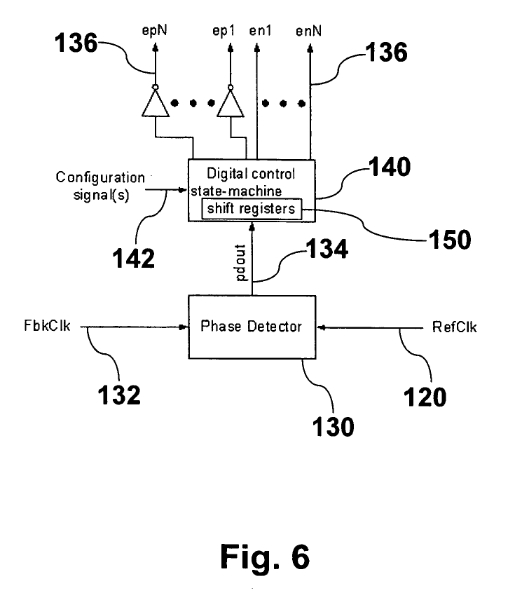

FIG. 6 illustrates an embodiment of a phase detector circuit and digital control circuit according to the inventive principles of this patent disclosure. Referring to FIG. 6, the delay line output signal on line 132 is fed back and applied to the phase detector 130 along with the periodic reference signal on line 120. The output signal on line 134 is generated by the phase detector 130 in response to the detected phase difference, and applied to the digital control unit 140. The digital control unit 140 may then generate digital control signals on lines 136, labeled enl to enN, and ep1 to epN, to tune the bias control circuit 116 illustrated in FIG. 3. Further, the digital control unit 140 generates digital control signals that cause the bias control circuit to adjust the delay-per-stage of the delay line 114 slightly up or slightly down.

The configuration signal on line 142 may also be applied to the digital control unit 140 to determine an operational mode, as discussed above with reference to the embodiment illustrated in FIG. 3. The digital control unit 140 may include one or more digital state machines that generate the appropriate digital control codes. The digital control unit 140 may further include one or more shift registers 150 to store (or freeze) the generated digital codes according to the operational mode. The digital control unit 140 may also include a glitch filter to prevent glitches on the phase detector output signal on line 134 from propagating as valid inputs.

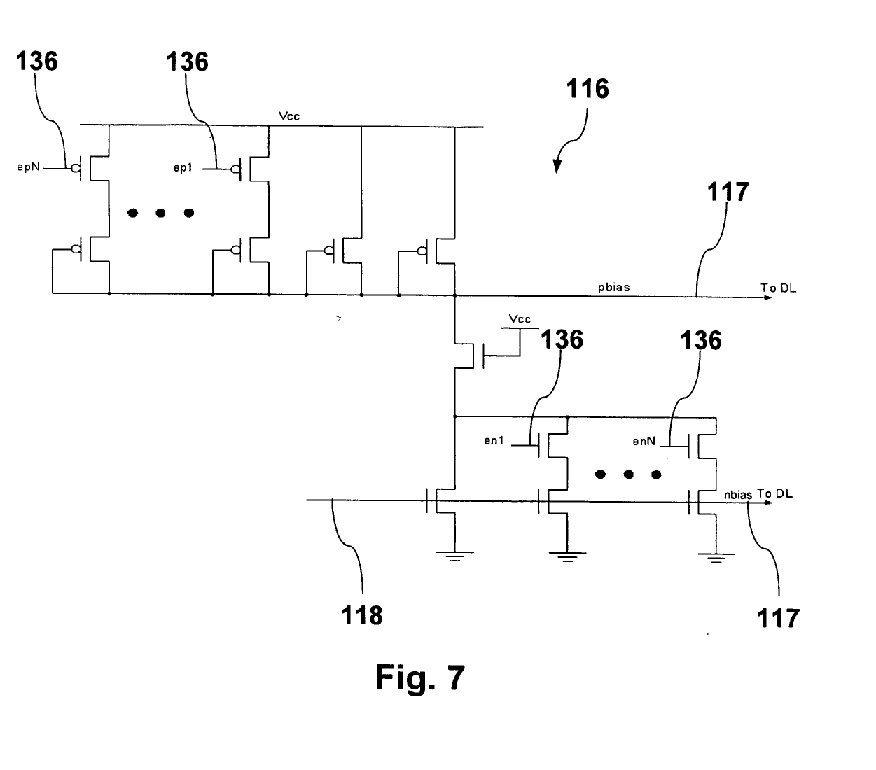

FIG. 7 illustrates an embodiment of a local bias control circuit according to the inventive principles of this patent disclosure. Referring to FIG. 7, the nbias and pbias signals are the local control voltages that are applied to the delay line 114 as illustrated in FIG. 4.

The digital control codes (en1 to enN, and ep1 to epN) on line 136 are applied to the bias control circuit 116, and are used to adjust the delay-per-stage. If all of the digital control codes ep1 to epN are at a logic 1, i.e., high, and all of the digital control codes enl to enN are at a logic 0, i.e., low, the control signal on line 118 determines the nbias and pbias control voltages without adjustment. Each successive digital control code enabled (e.g., ep1 changed to a logic 0 or en1 changed to a logic 1) provides more delay adjustment in the desired direction.

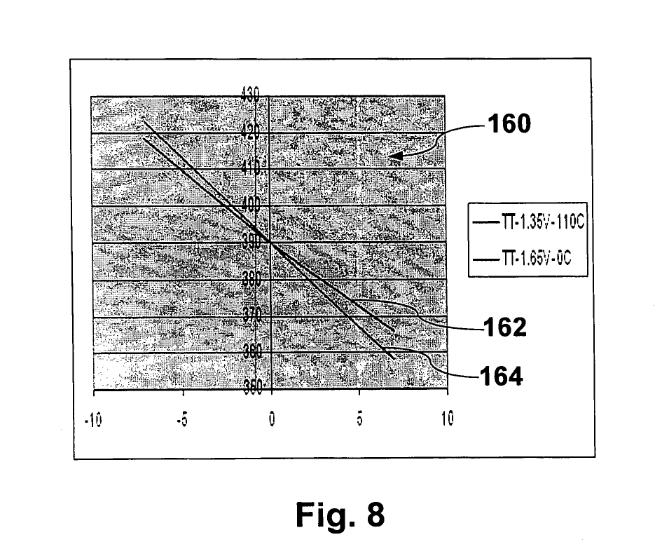

FIG. 8 illustrates an example of experimental tuning results according to the inventive principles of this patent disclosure. Referring to FIG. 8, the graph 160 shows results from a 14 bit control code, where seven bits are allocated between enl and en7 and seven bits are allocated between ep1 and ep7. The x-axis of graph 160 represents the number of digital control codes that are activated in a particular direction (i.e., how many of codes ep1 through ep7 are activated or how many of codes enl through en7 are activated), and the y-axis of graph 160 represents the delay-per-stage in picoseconds. Using this example configuration, an experimental result provided approximately a +/−30 picosecond tune range for the clock circuit, with about four picoseconds of delay adjustment per activated digital control code 136. The dark line 162 represents an experimental result with a die voltage of 1.35 volts and a die temperature of 110 degrees Celsius. The lighter line 164 represents an experimental result with a die voltage of 1.65 volts and a die temperature of 0 degrees Celsius.

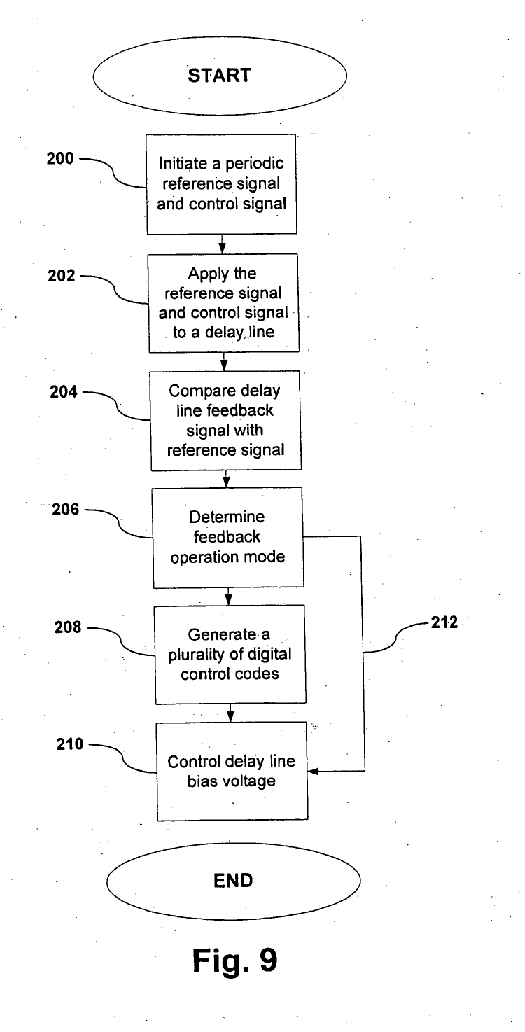

FIG. 9 illustrates an embodiment of a method for implementing a clock circuit according to the inventive principles of this patent disclosure. Referring to FIG. 9 and FIG. 3, a periodic reference signal on line 120 and a control signal on line 118 are initiated 200. The control signal on line 118 is initiated by a master signal control unit, which may include a locked-loop signal generator. In some embodiments, the periodic reference signal on line 120 may be also initiated by the master signal control unit. However, in other embodiments, the periodic reference signal on line 120 may be initiated by a different signal generating unit than the master signal control unit used for generating the control signal on line 118.

The periodic reference signal on line 120 and the control signal on line 118 are then applied to a delay line 114, 202. The control signal on line 118 may be used to determine the delay-per-stage of the delay line 114. In addition, the control signal on line 118 may further be a current control signal. A delay line feedback signal on line 132 is generated by the delay line 114 and compared with the reference signal on line 120, 204. In some embodiments, the phase of the delay line feedback signal on line 132 is compared with the phase of the periodic reference signal on line 120.

Next, a feedback operation mode is determined 206. The feedback operation mode may include disabled, lock once and freeze, periodic re-lock and freeze, and continuous running, which are described above. In a feedback operation mode, such as disabled, or where a particular operation mode is locked, the embodiment of this method controls at least one of the bias voltages of the delay line 114, 210, 212 based on default or previously stored control codes. However, if the feedback operation mode is such that the phase comparison is required to set or update the control codes, then a plurality of digital control codes are generated in response to the phase comparison 208. These digital control codes may further be stored in at least one shift register 150 illustrated in FIG. 6. Next, at least one bias voltage of the delay line 114 is controlled in response to these newly generated control codes 210.

The embodiments described herein may be modified in arrangement and detail without departing from the inventive principles. Accordingly, such changes and modifications are considered to fall within the scope of the following claims.

1. A clock circuit comprising:
a delay line having an input terminal for receiving a periodic signal;
a phase detector for detecting a phase difference between the periodic signal and a delay-line output signal generated in response to the periodic signal; and
a bias control circuit for adjusting at least one bias voltage applied to the delay line in response to a signal related to the detected phase difference.

2. The clock circuit of claim 1, wherein the clock circuit further comprises a locked-loop signal generator for generating the periodic signal.

3. The clock circuit of claim 2, wherein the locked-loop signal generator comprises a phase locked-loop.

4. The clock circuit of claim 2, wherein the locked-loop signal generator further generates a control signal used in determining the bias voltage applied to the delay line.

5. The clock circuit of claim 4, wherein the control signal generated by the locked-loop signal generator is applied to the bias control circuit and the delay line.

6. The clock circuit of claim 4, wherein the control signal generated by the locked-loop signal generator is used in determining a delay-per-stage for the delay line.

7. The clock circuit of claim 4, wherein the control signal generated by the locked-loop signal generator comprises a current signal.

8. The clock circuit of claim 1, further comprising a digital control unit for generating a plurality of digital codes in response to the detected phase difference, wherein the plurality of digital codes are applied to the bias control circuit to adjust the bias voltage of the delay line.

9. The clock circuit of claim 8, wherein a configuration control signal is further applied to the digital control unit to determine an operation mode.

10. The clock circuit of claim 9, wherein the operation mode is selected from a group comprising disabled, lock once and freeze, periodic re-lock and freeze, and continuous running.

11. The clock circuit of claim 9, wherein the digital control unit further comprises at least one shift register to store the plurality of digital codes according to the operation mode.

12. The clock circuit of claim 8, wherein the digital control unit further includes a glitch filter.

13. A method for generating multi-phase clock signals comprising:
generating a master clock signal;
applying the master clock signal to a delay-line;
comparing a phase of an output signal of the delay-line with a phase of the master clock signal; and
controlling at least one bias voltage of the delay line in response to the phase difference.

14. The method of claim 13, wherein controlling at least one bias voltage comprises generating a plurality of digital codes in response to the phase difference to adjust at least one bias voltage of the delay line.

15. The method of claim 13, further comprising generating a control signal with a locked-loop signal generator that is applied to the delay line.

16. The method of claim 15, wherein the control signal determines a delay-per-stage for the delay line.

17. The method of claim 15, wherein the generated control signal comprises a current signal.

18. The method of claim 13, further comprising selecting a feedback operation mode of the delay line.

19. The method of claim 18, wherein the feedback operation mode is selected from a group comprising disabled, lock once and freeze, periodic re-lock and freeze, and continuous running.

20. The method of claim 18, further comprising storing the plurality of digital codes in at least one shift register according to the selected feedback operation mode.

21. A method of eliminating clock phase error in a multi-phase clock, comprising:
initiating a reference delay-per-stage control signal in a master signal control unit;
applying a reference clock signal and the reference delay-per-stage control signal to a delay line;
comparing a feedback signal generated by the delay line in response to the reference clock signal with the reference clock signal;
generating a plurality of digital control codes related to the compared signals; and
tuning the reference delay-per-stage in response to the digital control codes to accommodate clock phase error.

22. The method of claim 21, further comprising selecting a feedback operation mode of the multi-phase clock.

23. The method of claim 21, further comprising storing the digital control codes in at least one shift register according to the selected feedback operation mode.

24. The method of claim 21, wherein the digital control codes have a tune range of about +/−30 picoseconds.

25. A multi-phase clocking system comprising:
a memory controller including a master locked-loop signal generator structured to initiate a control signal;
a first memory device including a first slave delay line structured to receive a first periodic signal and the control signal; and
a second memory device including a second slave delay line structured to receive a second periodic signal and the control signal,
wherein the first slave delay line and the second slave delay line each include:
a phase detector for detecting a phase difference between the periodic signal and a respective delay line output signal generated in response to the periodic signal, and
a bias control circuit for adjusting at least one bias voltage of the respective delay line in response to a signal related to the respective detected phase difference.

26. The system of claim 25, wherein the phase detector and bias control circuit of each slave delay line synchronize a delay-per stage of the first slave delay line with a delay-per-stage of the second slave delay line.

27. The system of claim 25, wherein the first periodic signal and the second periodic signal are the same signal.

28. The system of claim 25, wherein the first slave delay line and the second slave delay line each further include a digital control unit for generating a plurality of digital codes in response to the detected phase difference, wherein the plurality of digital codes are applied to the bias control circuit to adjust the bias voltage of the delay line.

29. The system of claim 28, wherein each digital control unit further includes:
an applied configuration control signal to determine an operation mode; and
at least one shift register to store the plurality of digital codes according to the operation mode.

30. The system of claim 28, wherein each digital control unit further includes at least one digital state machine for generating the digital codes.
